(19) United States
(12) Patent Application Publication
(10) Pub. No.: US 2025/0126940 A1
(43) Pub. Date: Apr. 17, 2025

(54) MICRO LED DISPLAY PANEL

(71) Applicant: JADE BIRD DISPLAY (SHANGHAI) LIMITED, SHANGHAI (CN)

(72) Inventors: Jin CAO, Shanghai (CN); Jian GUO, Shanghai (CN)

(21) Appl. No.: 18/911,264

(22) Filed: Oct. 10, 2024

(30) Foreign Application Priority Data
Oct. 13, 2023 (WO) PCT/CN2023/124487

(51) Int. Cl. H01L 33/60; H01L 25/16; H01L 33/30

(52) U.S. Cl. CPC H10H 20/856; H01L 25/167; H10H 20/824

(57) ABSTRACT

A micro LED display panel includes a micro LED array area including a plurality of micro LED structures. Each of the micro LED structures includes: a first type epitaxial layer; a light emitting layer formed on the first type epitaxial layer; and a second type epitaxial layer formed on the light emitting layer. The second type epitaxial layer includes: a micro lens structure and a bottom structure, the micro lens structure and the bottom structure being an integrative structure.

### CROSS-REFERENCE TO RELATED APPLICATIONS

The present disclosure claims the benefits of priority to PCT Application No. PCT/CN2023/124487, filed on Oct. 13, 2023, which is incorporated herein by reference in its entirety.

### TECHNICAL FIELD

The present disclosure generally relates to micro display technology, and more particularly, to a micro light emitting diode (LED) display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuit (IC) back panel. Each pixel of the micro LED display panel is formed by one or more micro LEDs. The micro LED display panel can be a mono-color or multi-color panel. In particular, for a multi-color LED panel, each pixel may further include multiple sub-pixels formed by multiple micro LEDs, each of which corresponds to a different color. For example, three micro LEDs respectively corresponding to red, green, and blue colors may be superimposed to form one pixel. The different colors can be mixed to produce a broad array of colors.

Generally, a micro lens is provided on a micro LED and used for adjusting the light emitting angle. In the conventional micro LED panel manufacturing process forming the micro lens may increase the process complexity and difficulty.

### SUMMARY OF THE DISCLOSURE

Embodiments of the present disclosure provide a micro LED display panel. The micro LED display panel includes a micro LED array area including a plurality of micro LED structures. Each of the micro LED structures includes: a first type epitaxial layer; a light emitting layer formed on the first type epitaxial layer; and a second type epitaxial layer formed on the light emitting layer. The second type epitaxial layer includes: a micro lens structure and a bottom structure, the micro lens structure and the bottom structure being an integrative structure.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a sectional view of an exemplary micro LED display panel, according to some embodiments of the present disclosure.

FIG. 2 illustrates a structural diagram showing a sectional view of a variant of the micro LED display panel shown in FIG. 1, according to some embodiments of the present disclosure.

FIG. 3 illustrates a structural diagram showing a sectional view of another exemplary micro LED display panel, according to some embodiments of the present disclosure.

FIG. 4 illustrates a structural diagram showing a top view of an exemplary micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

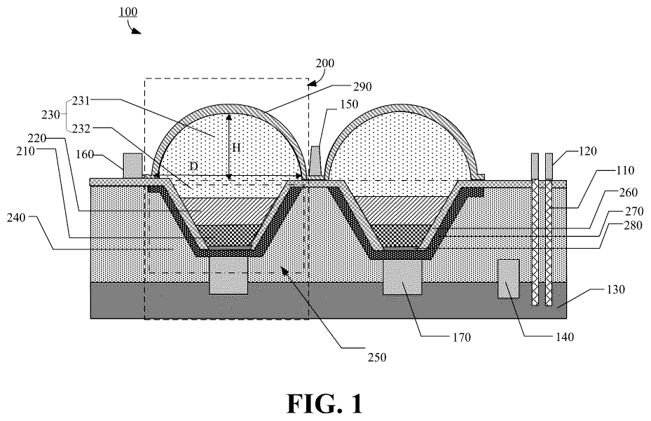

FIG. 1 illustrates a structural diagram showing a sectional view of an exemplary micro LED display panel 100, according to some embodiments of the present disclosure. Referring to FIG. 1, micro LED display panel 100 includes a micro LED array area including a plurality of micro LED structures 200. In this example, two micro LED structures 200 are shown only for descriptive purposes. It can be understood that additional micro LED structure 200 can be incorporated in a micro LED display panel. As shown in FIG. 1, micro LED structure 200 includes a first type epitaxial layer 210, a light emitting layer 220, and a second type epitaxial layer 230. Light emitting layer 220 is formed on first type epitaxial layer 210, and second type epitaxial layer 230 is formed on light emitting layer 220. First type epitaxial layer 210 is a P-type epitaxial layer. A material of first type epitaxial layer 210 is one or more of GaN, AlGaN, GaP, AlGaInP, or AlInP. Light emitting layer 220 is a quantum well layer. A material of light emitting layer 220 is selected from one or more of InGaN, AlGaN, or AlGaInP.

Second type epitaxial layer 230 further includes a micro lens structure 231 and a bottom structure 232 on light emitting layer 220. Micro lens structure 231 is configured to adjust light emitting angles. Micro lens structure 231 and bottom structure 232 form an integrated structure. That is, during manufacturing, second type epitaxial layer 230 can be etched to form micro lens structure 231 and bottom structure 232. Materials of micro lens structure 231 and bottom structure 232 are the same. Second type epitaxial layer 230 is an N-type epitaxial layer. A material of second type epitaxial layer 230 is selected from one or more of AlInP, AlGaInP, GaN, or AlGaN.

In some embodiments, micro lens structure 231 is semi-spherical, conical, pyramidal, cylindrical, or circular truncated conical. A height H of micro lens structure 231 is in a range of 0.05 μm to 10 μm, and a diameter D of a bottom cross section of micro lens structure 231 is in a range of 0.5 μm to 10 μm.

With this structure, micro lens structure 231 can be etched from second type epitaxial layer 230 so that the manufacturing process is simplified, which may reduce cost and improve productively.

In some embodiments, a size of micro lens structure 231 and a thickness of bottom structure 232 can be adjusted to obtain a better light emission performance. Since material of micro lens structure 231 is AlInP, AlGaInP, GaN, or AlGaN, light emission efficiency can be increased by 15% to 18% compared with other micro lenses.

In some embodiments, each micro LED structure 200 further includes a dielectric layer 240 formed between adjacent mesa structures 250 of adjacent micro LED structures 200. As shown in FIG. 1, mesa structure 250 includes first type epitaxial layer 210, light emitting layer 220, and bottom structure 232 of second type epitaxial layer 230. In some embodiments, a sidewall of mesa structure 250 is inclined.

In some embodiments, micro LED structure 200 further includes a passivation layer 260 formed on a sidewall surface of mesa structure 250. In some embodiments, passivation layer 260 is further formed on a top surface of dielectric layer 240. Passivation layer 260 is configured to provide protection for mesa structure 250 during manufacturing. A material of the passivation layer can be selected from one or more of SiO₂, Si₃N₄, or Al₂O₃.

In some embodiments, micro LED structure 200 further includes a reflective layer 270 formed on a sidewall surface of passivation layer 260. In some embodiments, reflective layer 270 is further formed on a bottom of each mesa structure 250. A material of reflective layer 270 can be selected from one or more of Al, Ag, Ti, Pt, Au, Ni, Cr, or Sn.

Reflective layer 270 can reflect light towards micro lens structure 231, thereby improving the light emission efficiency. For example, the light emission efficiency can increase 40% to 100%.

In some embodiments, micro LED display panel 100 further includes one or more IO (input/output) vias 110 and one or more top connection pads 120 respectively corresponding to the one or more IO vias 110. IO vias 110 are formed in dielectric layer 240 and through the passivation layer 260. IO vias 110 are provided outside the micro LED array area, for example, at an edge of micro LED display panel 100. One top connection pad 120 is formed on a top of one IO via 110. That is, one top connection pad 120 corresponds to one IO via 110.

Micro LED display panel 100 further includes an integrated circuit (IC) backplane 130 provided at a bottom of dielectric layer 240. One or more bottom connection pads 140 are provided on a top of IC backplane 130. Bottom connection pad 140 can be used for alignment during bonding process.

In some embodiments, a bottom contact 280 is further formed on the bottom of mesa structure 250, i.e., on a bottom of first type epitaxial layer 210, and on an inner surface of reflective layer 270. Bottom contact 280 is connected with reflective layer 270 and bonded with a bottom pad 170 of IC backplane 130. Bottom pad 170 can be electrically connected with a bottom of a bottom of one IO via. Therefore, top connection pad 120 can be electrically connected with bottom pad 170 through IO via 110.

In some embodiments, micro LED structure 200 further includes a top transparent conductive layer 290 formed on a surface of micro lens structure 231. Top transparent conductive layer 290 is selected from one of ITO (Indium Tin Oxide), Al doped ZnO, or Ga doped ZnO. A thickness of top transparent conductive layer 290 is in a range of 5 nm to 500 nm. Since a refractivity of top transparent conductive layer 290 is between a refractivity of second type epitaxial layer 230 and a refractivity of air, top transparent conductive layer 290 formed on the surface of micro lens structure 231 can reduce energy loss, e.g., Fresnel reflection loss, of the light emission. In some embodiments, top transparent conductive layer 290 continuously covers a whole surface of second type epitaxial layer 230. Therefore, top transparent conductive layer 290 can connect all the micro LED structures 200 in micro LED display panel 100 and provide electrical conductivity for micro LED structure 200.

Micro LED display panel 100 further includes a top contact 150 on top transparent conductive layer 290 between the adjacent micro lens structures 231. In some embodiments, micro LED display panel 100 further includes an electrode pad 160 formed on an edge of the micro LED array area and connected with top transparent conductive layer 290.

As shown in FIG. 1, a sidewall of top transparent conductive layer 290 is connected with a sidewall of electrode pad 160. A top of electrode pad 160 is higher than a top of the end of top transparent conductive layer 290. In some embodiments, electrode pad 160 and top contact 150 are interconnected, for example, electrode pad 160 and top contact 150 are interconnected to form a mesh, to improve conductive connection performance for top transparent conductive layer 290. Electrode pad 160 and top connection pad 120 can be configured to receive a control signal, for example, from a signal source, to control micro LED display panel 100. For example, electrode pad 160 and top connection pad 120 can be connected with an external circuit to receive control signals to control each micro LED structure 200 independently.

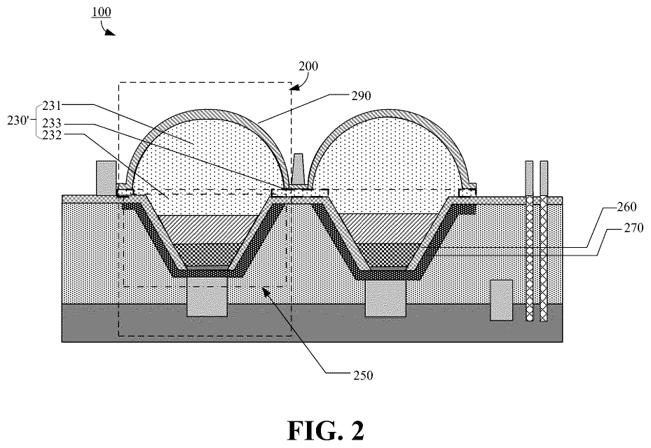

FIG. 2 illustrates a structural diagram showing a sectional view of a variant of micro LED display panel 100, according to some embodiments of the present disclosure. As shown in FIG. 2, a second type epitaxial layer 230′ further includes, in addition to micro lens structure 231 and bottom structure 232, an extrusion portion 233 interconnected between adjacent micro LED structures 200. Extrusion portion 233 extends along a horizontal direction. Passivation layer 260 is formed on a bottom surface of extrusion portion 233 and on a sidewall surface of mesa structure 250.

As shown in FIG. 2, reflective layer 270 is formed on a sidewall surface of passivation layer 260 and on at least part of bottom surface of passivation layer 260 under the bottom surface of extrusion portion 233.

In some embodiments, top transparent conductive layer 290 is formed on a surface of micro lens structure 231 and on a top surface of extrusion portion 233.

Description of other features of micro LED display panel 100 may be found by referring to such features described above with reference to FIG. 1, which will not be repeated here.

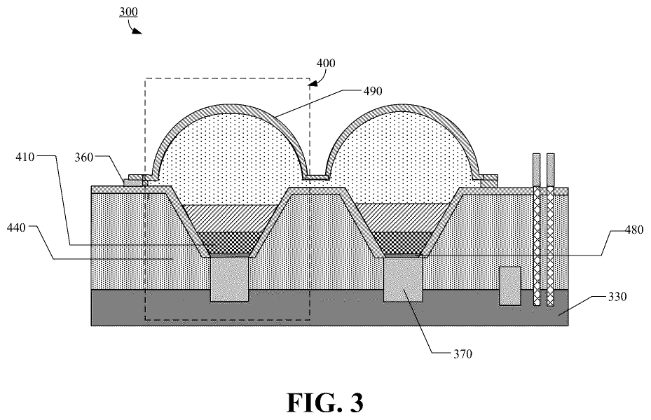

FIG. 3 illustrates a structural diagram showing a sectional view of another micro LED display panel 300, according to some embodiments of the present disclosure. As shown in FIG. 3, micro LED display panel 300 includes one or more micro LED structures 400 and an IC backplane 330 formed at a bottom of a dielectric layer 440. Micro LED structure 400 further includes a bottom contact 480 formed at a bottom of a first type epitaxial layer 410 and bonded with a bottom pad 370 of IC backplane 330.

Referring to FIG. 3, in this embodiment, an end of a top transparent conductive layer 490 is formed on part of a top of an electrode pad 360 and on a sidewall of electrode pad 360. Electrode pad 360 is provided for connecting to an external circuit.

Description of other features of micro LED display panel 300 may be found by referring to similar features described above with reference to FIG. 1 for micro LED display panel 100, which will not be repeated here.

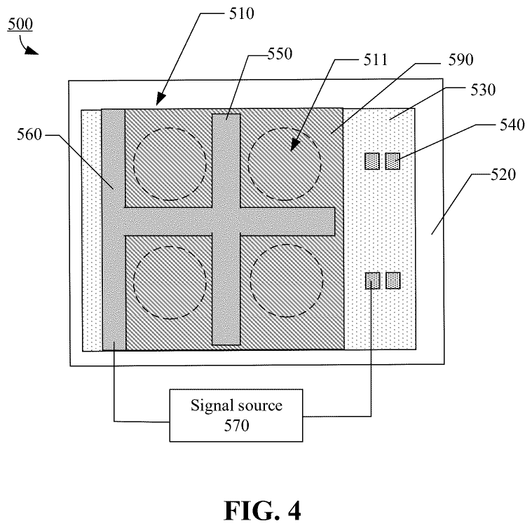

FIG. 4 illustrates a structural diagram showing a top view of a micro LED display panel 500, according to some embodiments of the present disclosure. Referring to FIG. 4, micro LED display panel 500 includes a micro LED array area 510 and an IC (integrated circuit) backplane 520 (e.g., IC backplane 130 in FIG. 1 and IC backplane 330 in FIG. 3). Micro LED array area 510 is located on IC backplane 520 to form an image display area of micro LED display panel 500. The rest of the area on IC backplane 520 not covered by micro LED array area 510 is formed as a non-functional area. IC backplane 520 is formed at the back surface of micro LED array area 510 with a part extending outside of, i.e., not covered by, micro LED array area 510. Micro LED array area 510 includes a plurality of micro LED structures 511 (e.g., micro LED structure 200 in FIG. 1 and micro LED structure 400 in FIG. 3) provided in an array. It can be understood that in FIG. 4, micro LED array area 510 including 2×2 micro structures is showing only for illustrative purpose. IC backplane 520 is configured to control the plurality of micro LED structures 511. IC backplane 520 may include a bottom pad array (not shown) corresponding to micro LED array area 510. The bottom pad array includes a plurality of bottom pads (e.g., bottom pad 170 in FIG. 1, and bottom pad 370 in FIG. 3) such that one bottom pad corresponds to one micro LED structure 511. One micro LED structure of the plurality of micro LED structures is electrically connected with one bottom pad of the plurality bottom pads.

In some embodiments, a top transparent conductive layer 590 (for example, top transparent conductive layer 290 in FIG. 1 and top transparent conductive layer 490 in FIG. 3) of micro LED structure 511 is interconnected with each of the plurality of micro LED structures 511. That is, the top transparent conductive layer is continuously formed on a top of micro LED array area 510, and connected with every micro LED structure 511. An electrode pad 560 (e.g., electrode pad 160 in FIG. 1 and electrode pad 360 in FIG. 3) is formed on an edge of micro LED array area 510 and connected with top transparent conductive layer 590. In some embodiments, a top contact 550 (e.g., top contact 150 in FIG. 1) is provided on top transparent conductive layer 590 between the adjacent micro LED structures 511. As shown in FIG. 4, electrode pad 560 and top contact 550 are interconnected. One or more top connection pads 540 (e.g., top connection pad 120 in FIG. 1) respectively corresponding to the one or more IO vias to electrically connected with IC backplane 520.

In some embodiments, micro LED display panel 500 further includes a signal source 570 electrically connected with IC backplane 520 and top transparent conductive layer 590. For example, signal source 570 electrically connected with top connection pad 540 and electrode pad 560.

Each micro LED structure herein (e.g., micro LED structure 200 in FIG. 1 and micro LED structure 400 in FIG. 3) has a very small volume. The light emitting area of the micro LED display panel, e.g., micro LED display panel 500, is very small, such as 1 mm×1 mm, 3 mm×5 mm, etc. In some embodiments, the light emitting area is the area of the micro LED array area in the micro LED display panel. Micro LED display panel 500 includes one or more micro LED structures 511 that form a pixel array in which the micro LED structures are pixels, such as a 1600×1200, 680×480, or 1920×1080-pixel array. The diameter of each micro LED is in the range of about 200 nm to 2 μm.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

The embodiments may further be described using the following clauses:
1. A micro LED display panel, comprising a micro LED array area including a plurality of micro LED structures, wherein each of the micro LED structures comprises:
a first type epitaxial layer;
a light emitting layer formed on the first type epitaxial layer; and
a second type epitaxial layer formed on the light emitting layer, wherein the second type epitaxial layer comprises:
   a micro lens structure and a bottom structure, the micro lens structure and the bottom structure being an integrated structure.
2. The micro LED display panel according to clause 1, wherein a mesa structure comprises the first type epitaxial layer, the light emitting layer, and the bottom structure of the second type epitaxial layer; and the micro LED structure further comprising a dielectric layer formed between adjacent mesa structures of adjacent micro LED structures.
3. The micro LED display panel according to clause 2, wherein a sidewall of the mesa structure is inclined.
4. The micro LED display panel according to clause 2 or 3, wherein the micro LED structure further comprises: a passivation layer formed on a sidewall surface of the mesa structure.
5. The micro LED display panel according to clause 4, wherein the passivation layer is further formed on a top surface of the dielectric layer.
6. The micro LED display panel according to clause 4, further comprising:
one or more IO (input/output) vias formed outside the micro LED array area and through the dielectric layer and the passivation layer;
one or more top connection pads corresponding to the one or more IO vias, wherein one top connection pad is formed on a top of one IO via;
an integrated circuit (IC) backplane provided at a bottom of the dielectric layer; and
one or more bottom pads provided on the IC backplane corresponding to plurality of micro LED structures, wherein a bottom of one IO via is bonded with one bottom pad.
7. The micro LED display panel according to clause 4, wherein the micro LED structure further comprises a reflective layer formed on a sidewall surface of a portion of the passivation layer.
8. The micro LED display panel according to clause 7, wherein the reflective layer is further formed on a bottom of the mesa structure.
9. The micro LED display panel according to clause 8, wherein a bottom contact is further formed on the bottom of the mesa structure and on an inner surface of the reflective layer.
10. The micro LED display panel according to any one of clauses 7 to 9, wherein a material of the reflective layer is selected from one or more of Al, Ag, Ti, Pt, Au, Ni, Cr, or Sn.
11. The micro LED display panel according to any one of clauses 4 to 10, wherein a material of the passivation layer is selected from one or more of SiO₂, Si₃N₄, or Al₂O₃.
12. The micro LED display panel according to clause 2, further comprising an integrated circuit (IC) backplane formed at a bottom of the dielectric layer.
13. The micro LED display panel according to clause 12, wherein the micro LED structure further comprises: a bottom contact formed at a bottom of the first type epitaxial layer and bonded with a bottom pad of the IC backplane.
14. The micro LED display panel according to clause 1, wherein the micro LED structure further comprises a top transparent conductive layer formed on a surface of the micro lens structure.
15. The micro LED display panel according to clause 14, wherein a material of the top transparent conductive layer is selected from one of ITO (Indium Tin Oxide), Al doped ZnO, or Ga doped ZnO.
16. The micro LED display panel according to clause 14, wherein the top transparent conductive layer continuously covers a whole surface of the second type epitaxial layer.
17. The micro LED display panel according to clause 16, further comprising a top contact formed on the top transparent conductive layer between adjacent micro lens structures.
18. The micro LED display panel according to any one of clauses 14 to 17, wherein a thickness of the top transparent conductive layer is in a range of 5 nm to 500 nm.
19. The micro LED display panel according to clause 14, further comprising an electrode pad formed on an edge of the micro LED array area and connected with the top transparent conductive layer.
20. The micro LED display panel according to clause 19, wherein an end of the top transparent conductive layer is formed on part of a top of the electrode pad and on a sidewall of the electrode pad.
21. The micro LED display panel according to clause 19, wherein a sidewall of the top transparent conductive layer is connected with a sidewall of the electrode pad.
22. The micro LED display panel according to clause 21, wherein a top of the electrode pad is higher than a top of an end of the top transparent conductive layer.
23. The micro LED display panel according to clause 14, further comprising:
an integrated circuit (IC) backplane provided at a bottom of the micro LED array area; and
a signal source electrically connected with the IC backplane and the top transparent conductive layer.
24. The micro LED display panel according to clause 1, wherein a material of the first type epitaxial layer is selected from one or more of GaN, AlGaN, GaP, AlGaInP, or AlInP; a material of the second type epitaxial layer is selected from one or more of AlInP, AlGaInP, GaN, or AlGaN; and the light emitting layer is a quantum well layer.
25. The micro LED display panel according to clause 1, wherein the micro lens structure and the bottom structure are made of a same material.
26. The micro LED display panel according to clause 25, wherein the micro lens structure is semi-spherical, conical, pyramidal, cylindrical, or circular truncated conical.
27. The micro LED display panel according to clause 25, wherein a height of the micro lens structure is in a range of 0.05 μm to 10 μm, and a diameter of a bottom cross section of the micro lens structure is in a range of 0.5 μm to 10 μm.
28. The micro LED display panel according to clause 2, wherein the second type epitaxial layer further comprises: an extrusion portion interconnected between adjacent micro LED structures.
29. The micro LED display panel according to clause 28, wherein the extrusion portion extends along a horizontal direction.
30. The micro LED display panel according to clause 28, wherein the micro LED structure further comprises: a passivation layer formed on a bottom surface of the extrusion portion and on a sidewall surface of the mesa structure.
31. The micro LED display panel according to clause 30, wherein the micro LED structure further comprises: a reflective layer formed on a sidewall surface of a portion of the passivation layer and on at least part under a bottom surface of the extrusion portion.
32. The micro LED display panel according to clause 30, wherein the micro LED structure further comprises: a top transparent conductive layer formed on a surface of the micro lens structure and on a top surface of the extrusion portion.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

1. A micro LED display panel, comprising a micro LED array area including a plurality of micro LED structures, wherein each of the micro LED structures comprises:
a first type epitaxial layer;
a light emitting layer formed on the first type epitaxial layer; and
a second type epitaxial layer formed on the light emitting layer, wherein the second type epitaxial layer comprises:
a micro lens structure and a bottom structure, the micro lens structure and the bottom structure being an integrated structure.

2. The micro LED display panel according to claim 1, wherein a mesa structure comprises the first type epitaxial layer, the light emitting layer, and the bottom structure of the second type epitaxial layer; and the micro LED structure further comprising a dielectric layer formed between adjacent mesa structures of adjacent micro LED structures.

3. The micro LED display panel according to claim 2, wherein a sidewall of the mesa structure is inclined.

4. The micro LED display panel according to claim 2, wherein the micro LED structure further comprises: a passivation layer formed on a sidewall surface of the mesa structure.

5. The micro LED display panel according to claim 4, wherein the passivation layer is further formed on a top surface of the dielectric layer.

6. The micro LED display panel according to claim 4, further comprising:
one or more IO (input/output) vias formed outside the micro LED array area and through the dielectric layer and the passivation layer;
one or more top connection pads corresponding to the one or more IO vias, wherein one top connection pad is formed on a top of one IO via;
an integrated circuit (IC) backplane provided at a bottom of the dielectric layer; and
one or more bottom pads provided on the IC backplane corresponding to plurality of micro LED structures, wherein a bottom of one IO via is bonded with one bottom pad.

7. The micro LED display panel according to claim 4, wherein the micro LED structure further comprises a reflective layer formed on a sidewall surface of a portion of the passivation layer.

8. The micro LED display panel according to claim 7, wherein the reflective layer is further formed on a bottom of the mesa structure.

9. The micro LED display panel according to claim 8, wherein a bottom contact is further formed on the bottom of the mesa structure and on an inner surface of the reflective layer.

10. The micro LED display panel according to claim 7, wherein a material of the reflective layer is selected from one or more of Al, Ag, Ti, Pt, Au, Ni, Cr, or Sn.

11. The micro LED display panel according to claim 4, wherein a material of the passivation layer is selected from one or more of SiO₂, Si₃N₄, or Al₂O₃.

12. The micro LED display panel according to claim 2, further comprising an integrated circuit (IC) backplane formed at a bottom of the dielectric layer.

13. The micro LED display panel according to claim 12, wherein the micro LED structure further comprises: a bottom contact formed at a bottom of the first type epitaxial layer and bonded with a bottom pad of the IC backplane.

14. The micro LED display panel according to claim 1, wherein the micro LED structure further comprises a top transparent conductive layer formed on a surface of the micro lens structure.

15. The micro LED display panel according to claim 14, wherein a material of the top transparent conductive layer is selected from one of ITO (Indium Tin Oxide), Al doped ZnO, or Ga doped ZnO.

16. The micro LED display panel according to claim 14, wherein the top transparent conductive layer continuously covers a whole surface of the second type epitaxial layer.

17. The micro LED display panel according to claim 16, further comprising a top contact formed on the top transparent conductive layer between adjacent micro lens structures

18. The micro LED display panel according to claim 14, wherein a thickness of the top transparent conductive layer is in a range of 5 nm to 500 nm.

19. The micro LED display panel according to claim 14, further comprising an electrode pad formed on an edge of the micro LED array area and connected with the top transparent conductive layer.

20. The micro LED display panel according to claim 19, wherein an end of the top transparent conductive layer is formed on part of a top of the electrode pad and on a sidewall of the electrode pad.

21. The micro LED display panel according to claim 19, wherein a sidewall of the top transparent conductive layer is connected with a sidewall of the electrode pad.

22. The micro LED display panel according to claim 21, wherein a top of the electrode pad is higher than a top of an end of the top transparent conductive layer.

23. The micro LED display panel according to claim 14, further comprising:
an integrated circuit (IC) backplane provided at a bottom of the micro LED array area; and
a signal source electrically connected with the IC backplane and the top transparent conductive layer.

24. The micro LED display panel according to claim 1, wherein a material of the first type epitaxial layer is selected from one or more of GaN, AlGaN, GaP, AlGaInP, or AlInP; a material of the second type epitaxial layer is selected from one or more of AlInP, AlGaInP, GaN, or AlGaN; and the light emitting layer is a quantum well layer.

25. The micro LED display panel according to claim 1, wherein the micro lens structure and the bottom structure are made of a same material.

26. The micro LED display panel according to claim 25, wherein the micro lens structure is semi-spherical, conical, pyramidal, cylindrical, or circular truncated conical.

27. The micro LED display panel according to claim 25, wherein a height of the micro lens structure is in a range of 0.05 μm to 10 μm, and a diameter of a bottom cross section of the micro lens structure is in a range of 0.5 μm to 10 μm.

28. The micro LED display panel according to claim 2, wherein the second type epitaxial layer further comprises: an extrusion portion interconnected between adjacent micro LED structures.

29. The micro LED display panel according to claim 28, wherein the extrusion portion extends along a horizontal direction.

30. The micro LED display panel according to claim 28, wherein the micro LED structure further comprises: a passivation layer formed on a bottom surface of the extrusion portion and on a sidewall surface of the mesa structure.

31. The micro LED display panel according to claim 30, wherein the micro LED structure further comprises: a reflective layer formed on a sidewall surface of a portion of the passivation layer and on at least part under a bottom surface of the extrusion portion.

32. The micro LED display panel according to claim 30, wherein the micro LED structure further comprises: a top transparent conductive layer formed on a surface of the micro lens structure and on a top surface of the extrusion portion.
